(19) United States
(12) Patent Application Publication
(10) Pub. No.: US 2012/0018719 A1
(43) Pub. Date: Jan. 26, 2012

(54) PHOTO TRANSISTOR

(75) Inventors: HSIAO-WEN ZAN, Hsinchu City (TW); HSIN-FEI MENG, Hsinchu City (TW); CHUANG-CHUANG TSAI, Hsinchu City (TW); WEI-TSUNG CHEN, Hsinchu City (TW); YU-CHIANG CHAO, Hsinchu City (TW)

(73) Assignee: NATIONAL CHIAO TUNG UNIVERSITY, HSINCHU CITY (TW)

(21) Appl. No.: 13/027,554

(22) Filed: Feb. 15, 2011

(30) Foreign Application Priority Data
Jul. 23, 2010 (TW) 099124447

(51) Int. Cl. H01L 29/12; H01L 31/113

(52) U.S. Cl. 257/43; 257/76; 257/290; 257/E33.053; 257/E29.068

(57) ABSTRACT

A phototransistor includes a substrate, a gate layer, a dielectric layer, an active layer, a source and a drain, and a light absorption layer. The gate layer is disposed on a top of the substrate, and the dielectric layer is disposed on a top of the gate layer. The active layer has a first bandgap and is disposed on a top of the dielectric layer, and the source and the drain are disposed on a top of the active layer. The light absorption layer has a second bandgap and is capped on the active layer, and the second bandgap is smaller than the first bandgap.

### FIELD OF THE INVENTION

The present invention relates to a phototransistor, and more particularly to a phototransistor capable of sensing light of different wavelengths.

### BACKGROUND OF THE INVENTION

Currently, wide-bandgap semiconductor devices, such as the metal-oxide transistor and the like, have the advantages of having excellent current driving ability, being able to be manufactured in a low-temperature environment, and having simple manufacturing process, and therefore become the new generation of high-potential devices. Among others, a semiconductor-based photosensor device usually uses photons to excite mobile carriers, and this condition is reflected in the current driving ability of the photosensor device. In the configuration of this type of photosensor device, there is included a simple photoconductor, a diode or a phototransistor. Wherein, the transistor is a three-terminal device capable of amplifying a photo-responsive signal and having good scalability and photo responsivity.

A lot of wide-bandgap semiconductors are materials with excellent transmission performance. For example, the metal-oxide materials are Group II-VI semiconductor materials with direct bandgap and transparency, and are very good photoelectric materials for applying to the display driving, light emitting or photosensor devices. However, due to the wide bandgap thereof, which is usually larger than 3 eV, these semiconductor materials have poor absorption of visible light, infrared light and long-wavelength electromagnetic waves. Please refer to FIG. 1 that is a transmittance spectrum of InGaSnO. As shown, the InGaSnO has an optical bandgap about 3.2 eV. Therefore, for the spectrum range from the visible light to the infrared light (with a wavelength>400 nm), the InGaSnO film is transparent. That is, the InGaSnO film would not significantly absorb electromagnetic waves within this wavelength range. Thus, the conventional wide-bandgap metal-oxide-semiconductor devices require structural correction if they are to be used as photosensor devices for sensing long-wavelength electromagnetic waves, such as invisible light and infrared light.

### SUMMARY OF THE INVENTION

It is therefore a primary object of the present invention to provide a phototransistor to overcome the problem of failing to sense the spectrum range from the visible light to the infrared light as found in the conventional phototransistor.

To achieve the above and other objects, the phototransistor according to an embodiment of the present invention includes a substrate, a gate layer, a dielectric layer, an active layer, a source and a drain, and a light absorption layer. The gate layer is disposed on a top of the substrate; and the dielectric layer is disposed on a top of the gate layer. The active layer has a first bandgap and is disposed on a top of the dielectric layer, and the source and the drain are disposed on a top of the active layer. The light absorption layer has a second bandgap and caps the active layer. The second bandgap is smaller than the first bandgap.

Preferably, the active layer is selected from the group consisting of In₂O₃, Ga₂O₃, SnO₂, MgO, ZnO, IZO, IGZO, and any chemical compound having at least one of the above-mentioned materials as a base material thereof.

Preferably, the first bandgap is at least 3 eV.

Preferably, the light absorption layer has a conduction band energy level higher than that of the active layer.

Preferably, the light absorption layer is selected from the group consisting of P3HT, PbPc, and Pentacene.

Preferably, the phototransistor further includes a filter layer being disposed on a top of the light absorption layer. The filter layer includes a third bandgap, which is smaller than the first bandgap and unequal to the second bandgap.

To achieve the above and other objects, another embodiment of the phototransistor according to the present invention includes a substrate, a gate layer, a dielectric layer, an active layer, a source, a drain, and a light absorption layer. The gate layer is disposed on a top of the substrate, and the dielectric layer is disposed on a top of the gate layer. The source and the drain are disposed on a top of the dielectric layer, and the active layer has a first bandgap and is disposed on a top of the source and the drain. The light absorption layer has a second bandgap and caps the active layer, and the second bandgap is smaller than the first bandgap.

Preferably, the active layer is selected from the group consisting of In₂O₃, Ga₂O₃, SnO₂, MgO, ZnO, IZO, IGZO, and any chemical compound having at least one of the above-mentioned materials as a base material thereof.

Preferably, the first bandgap is at least 3 eV.

Preferably, the light absorption layer has a conduction band energy level higher than that of the active layer.

Preferably, the light absorption layer is selected from the group consisting of P3HT, PbPc, and Pentacene.

Preferably, the phototransistor further includes a filter layer being disposed on a top of the light absorption layer. The filter layer includes a third bandgap, which is smaller than the first bandgap and unequal to the second bandgap.

With the above arrangements, the phototransistor according to the present invention has one or more of the following advantages:

(1) The phototransistor uses a narrow-bandgap light-absorbing material to cap the active layer, so as to increase the light sensitive range of the phototransistor; and

(2) By providing different filter layers on the top of the light absorption layer, it is able to selectively sense light of different wavelengths and thereby effectively increase the application flexibility of the phototransistor.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a transmittance spectrum of InGaSnO;

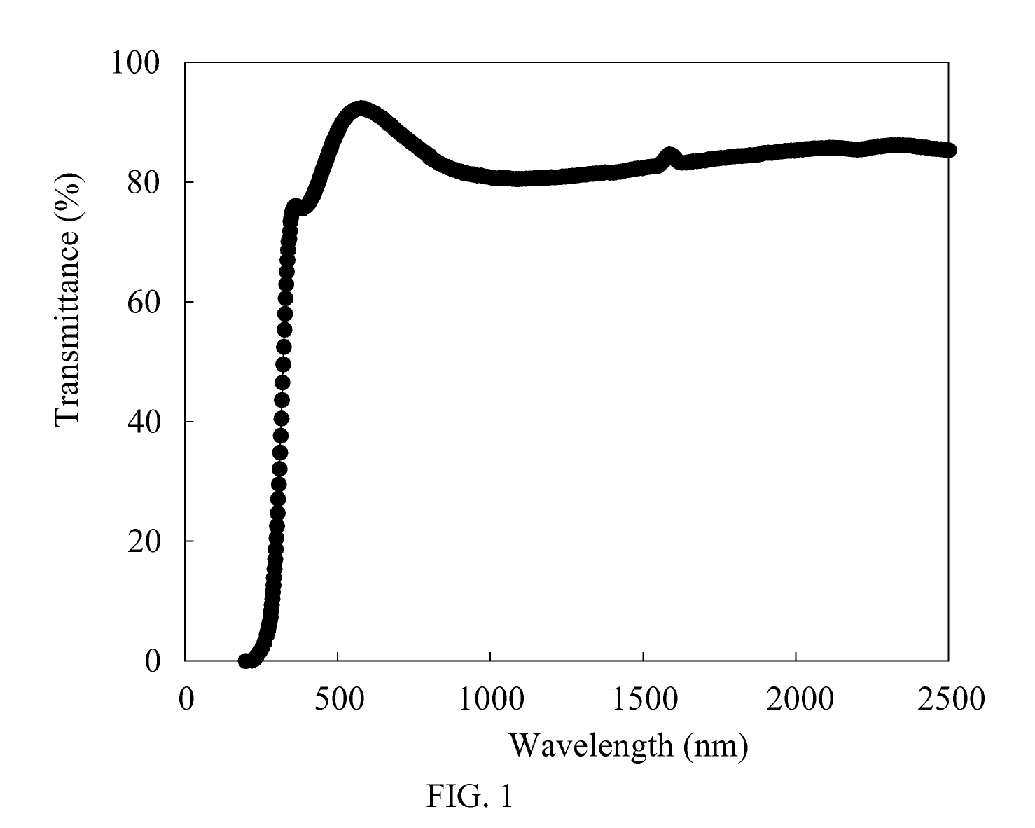

FIG. 2 is a conceptual view of a phototransistor according to the present invention;

FIG. 3 is a schematic energy level diagram of the phototransistor of the present invention;

FIG. 4 is a conceptual view of a first embodiment of the phototransistor of the present invention;

FIG. 5 shows the characteristic transfer curves of the phototransistor of the present invention;

FIG. 6 shows the photosensitivity of the phototransistor of the present invention;

FIG. 7 shows an instant light response curve of the phototransistor of the present invention obtained in a test conducted thereon;

FIG. 8 is a conceptual view of a second embodiment of the phototransistor of the present invention;

FIG. 9 is an absorption spectrum of the phototransistor of the present invention according to the second embodiment thereof; and

FIG. 10 is a flowchart showing the steps included in a process for manufacturing the phototransistor of the present invention.

### DETAILED DESCRIPTION OF THE PREFERRED EMBODIMENTS

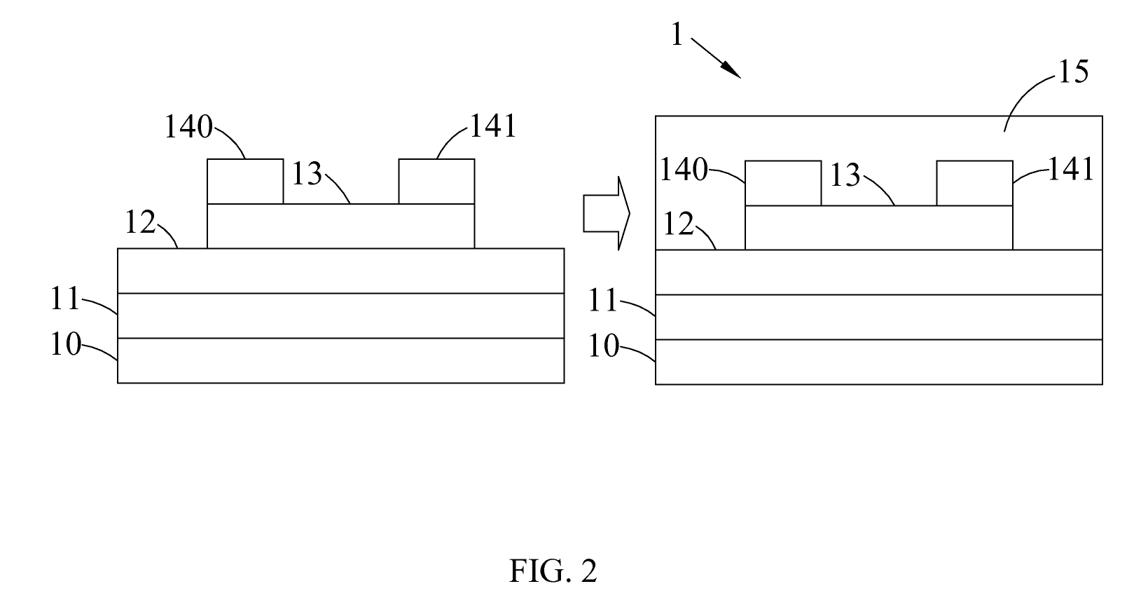

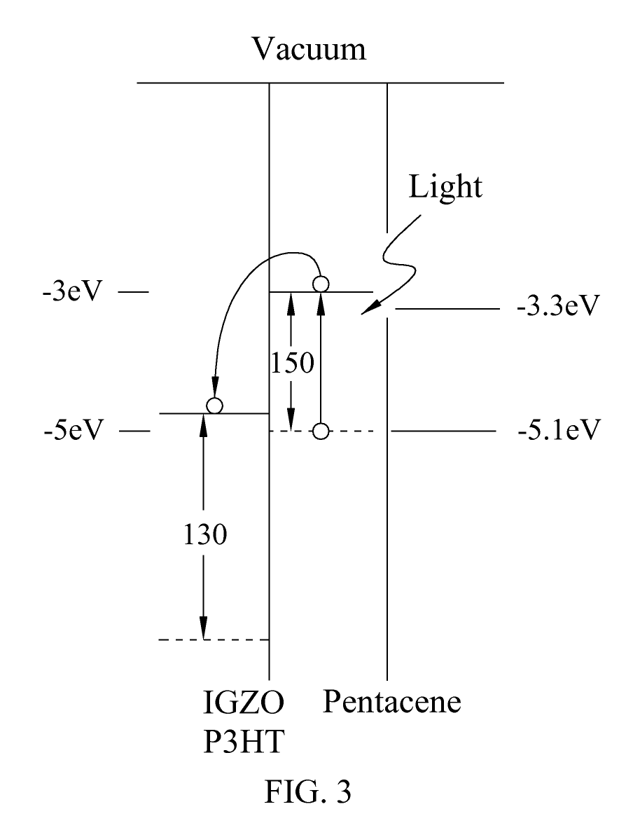

The present invention will now be described with some preferred embodiments thereof. For the purpose of easy to understand, elements that are the same in the preferred embodiments are denoted by the same reference numerals. Please refer to FIG. 2 that is a conceptual view of a phototransistor 1 according to the present invention. As shown, the phototransistor 1 includes a substrate 10, a gate layer 11, a dielectric layer 12, an active layer 13, a source 140 and a drain 141, and a light absorption layer 15. The gate layer 11 is disposed on a top of the substrate 10, and the dielectric layer 12 is disposed on a top of the gate layer 11. The active layer 13 has a first Bandgap 130, as shown in FIG. 3, and is disposed on a top of the dielectric layer 12. The source 140 and the drain 141 are disposed on a top of the active layer 13. In some other preferred embodiments of the present invention that are not shown in the drawings, the source 140 and the drain 141 are disposed on the dielectric layer 12 and the active layer 13 is disposed on top of the source 140 and the drain 141. In the illustrated embodiments of the present invention, the active layer 13 can be In₂O₃, Ga₂O₃, SnO₂, MgO, ZnO, InZnO (i.e. IZO), InGaZnO (i.e. IGZO), or a chemical compound having at least one of the above-mentioned materials as a base material thereof. The light absorption layer 15 can be P3HT having a bandgap of 2.1 eV, PbPc, or Pentacene having a bandgap of 1.8 eV.

Please also refer to FIG. 3 that is a schematic energy level diagram of the phototransistor of the present invention. In some embodiments of the present invention, the light absorption layer 15 has a second bandgap 150 and caps the active layer 13 as well as the source 140 and drain 141. However, in some preferred embodiments, the light absorption layer 15 could not cap the source 140 and the drain 141. The second bandgap 150 is smaller than the first bandgap 130. In some other preferred embodiments, the first bandgap 130 can be at least 3 electronic volts (eV) while the second bandgap is smaller than 3 eV. In this way, it is possible for the active layer 13 to yield a photoelectric response only to light having energy higher than 3 eV. Further, as shown in FIG. 3, the light absorption layer 15 has a conduction band energy level larger than that of the active layer 13. With this arrangement, when the light absorption layer 15 absorbs light with relatively longer wavelength, electrons in the generated electron-hole pairs can more easily migrate from the conduction band of the light absorption layer 15 to the conduction band of the active layer 13 to serve as carriers in the active layer 13.

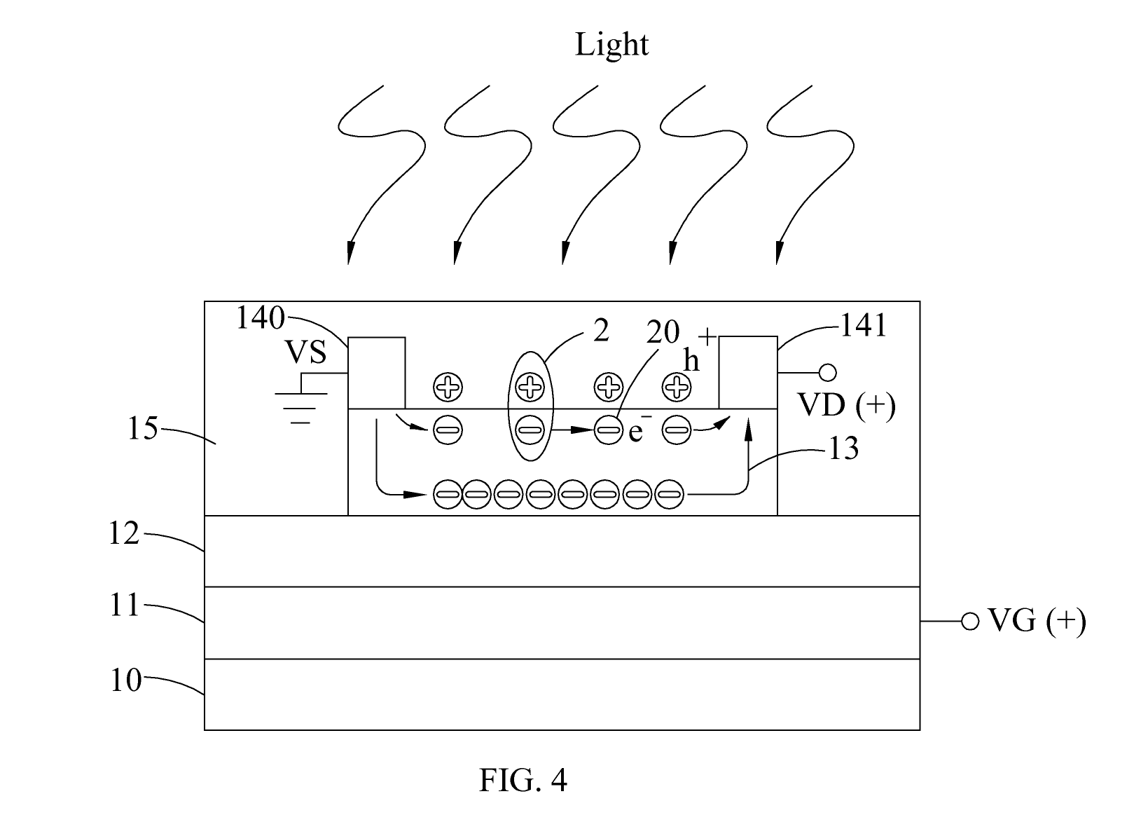

Please refer to FIG. 4 that is a conceptual view of a first embodiment of the phototransistor of the present invention. In the first embodiment, the active layer 13 is IGZO with an energy level about 3 eV for correspondingly absorbing light having a wavelength about 390 nm, which is substantially within the range of ultraviolet light. In this case, when it is desired to increase the sensitivity of the phototransistor 1 to the long-wavelength electromagnetic wave, such as the visible light or the infrared light, a solution proposed by the present invention is to cap the phototransistor 1 with a light absorption layer 15 that has a bandgap smaller than that of the active layer 13. Electrons generated by stimulating the light absorption layer 15 with light can be effectively injected into the active layer 13 of the phototransistor 1 to increase the conducting electrons. In the first embodiment, the light absorption layer 15 can be an organic semiconductor. Some types of organic semiconductors can be used to cap a metal-oxide-semiconductor without bringing significant electrical changes in the latter.

In the first embodiment, a layer of P3HT having a bandgap of 2.1 eV is used as the light absorption layer 15 to cap the IGZO transistor having a bandgap of 3.2 eV. The light absorption layer 15 is characterized by having a bandgap narrower than that of the active layer 13, and can therefore absorb electromagnetic waves with a relatively longer wavelength and relatively lower photon energy. With an energy band relation at a junction between the wide-bandgap IGZO and the narrow-bandgap organic semiconductor P3HT as that shown in FIG. 3, incident photons can be absorbed by the P3HT layer 15 to then generate carriers, which would migrate to the IGZO layer 13. As shown in FIG. 4, when incident light having photon energy smaller than the bandgap of the active layer 13 (IGZO) illuminates the phototransistor 1, the incident light is absorbed by the topmost light absorption layer 15 (P3HT) or by an interface between the active layer 13 and the light absorption layer 15 (P3HT/IGZO) to generate excitons (electron-hole pairs) 2. Then, the excitons 2 are respectively separated at the P3HT/IGZO interface to thereby increase the number of carriers 20 (i.e. electrons herein) in the active layer 13. The carriers 20 generated through light excitation can be conducted in the form of electrons in the IGZO active layer 13 to thereby produce photocurrent.

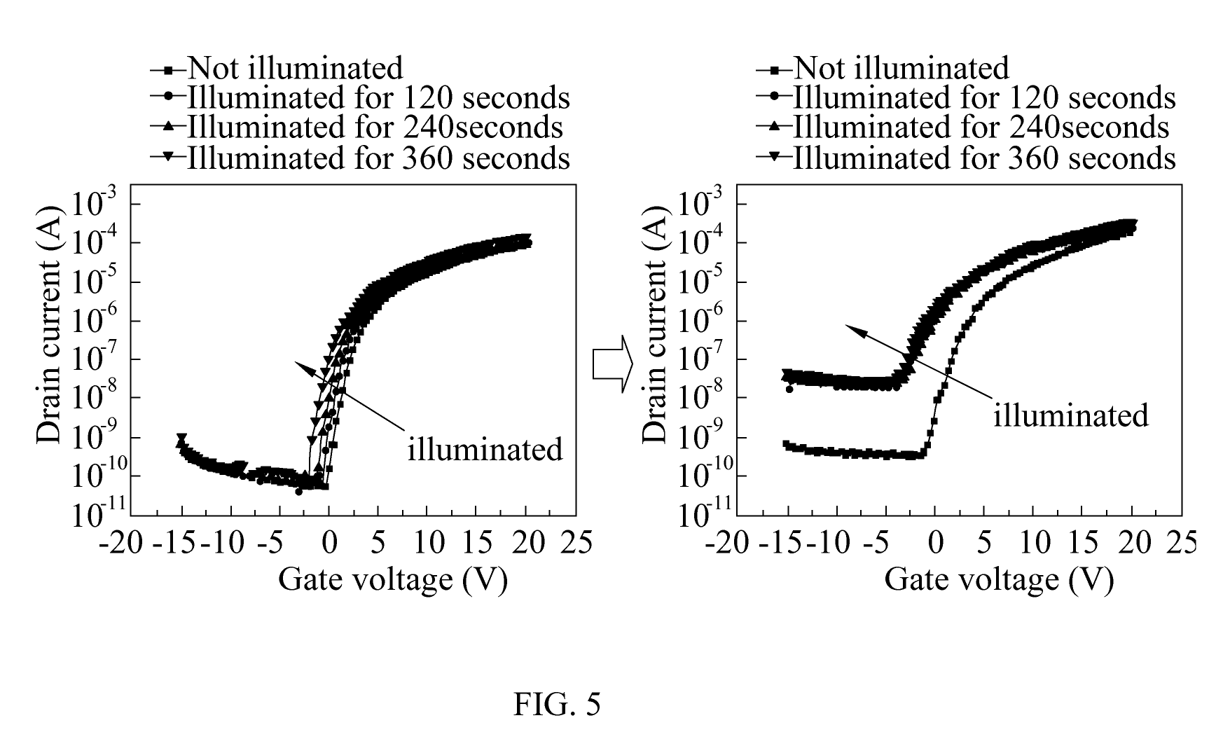

Please refer to FIG. 5 that shows characteristic transfer curves of the phototransistor of the present invention. As shown in FIG. 5, the characteristics of two different types of devices are compared. The phototransistor at the left part of FIG. 5 is a IGZO phototransistor without being capped by a P3HT light absorption layer 15, while the phototransistor at the right part of FIG. 5 is a IGZO phototransistor being capped by a P3HT light absorption layer 15. From the comparison results as shown in FIG. 5, it is found, after being illuminated by light, the phototransistor capped by the P3HT light absorption layer has significantly increased drain current when the gate voltage is unchanged. Therefore, it is proven the P3HT light absorption layer indeed enables the IGZO phototransistor to have relatively significant photo responsivity to white light.

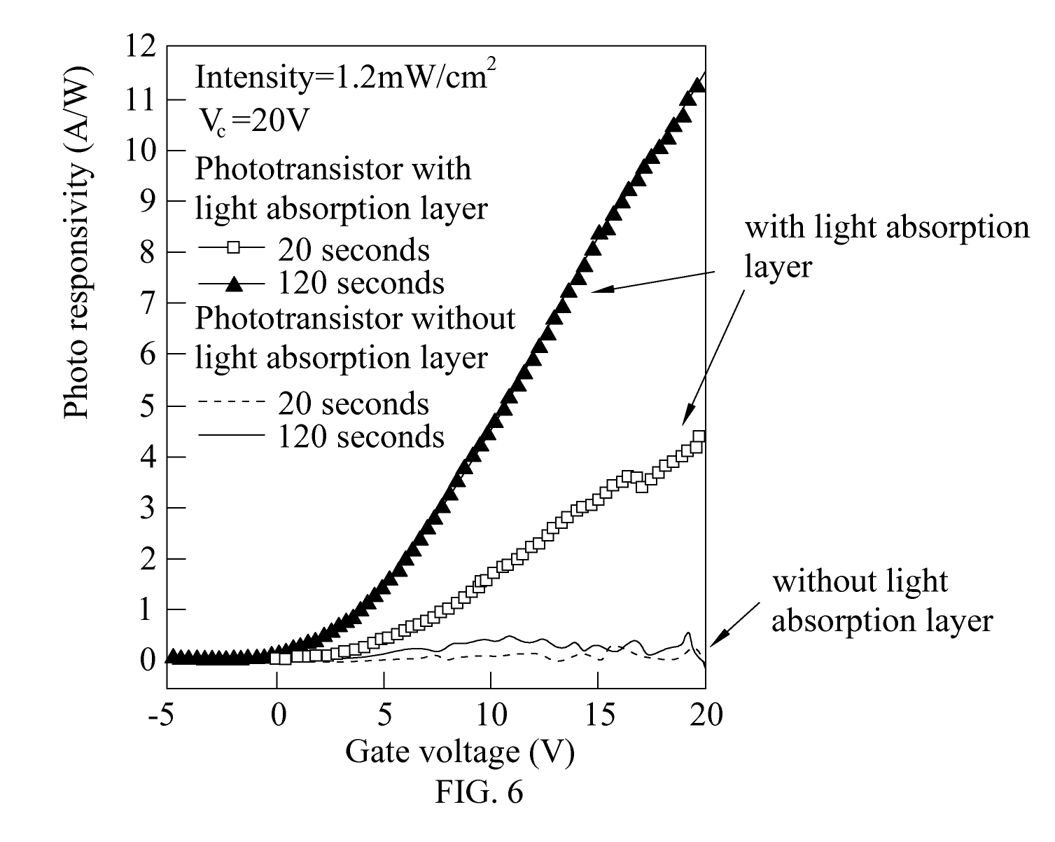

Please refer to FIG. 6 that shows the photosensitivity of the phototransistor of the present invention. As shown, the two upper curves represent the relation between the photo responsivity and the gate voltage of the P3HT-capped phototransistor when being illuminated by light for 120 seconds and 20 seconds, respectively. Meanwhile, the two lower curves represent the relation between the photo responsivity and the gate voltage of a standard phototransistor without being capped by P3HT when being illuminated by light for 120 seconds and 20 seconds, respectively. As can be clearly seen from FIG. 6, with the same gate voltage, the P3HT-capped phototransistor has photosensitivity superior to that of the standard phototransistor.

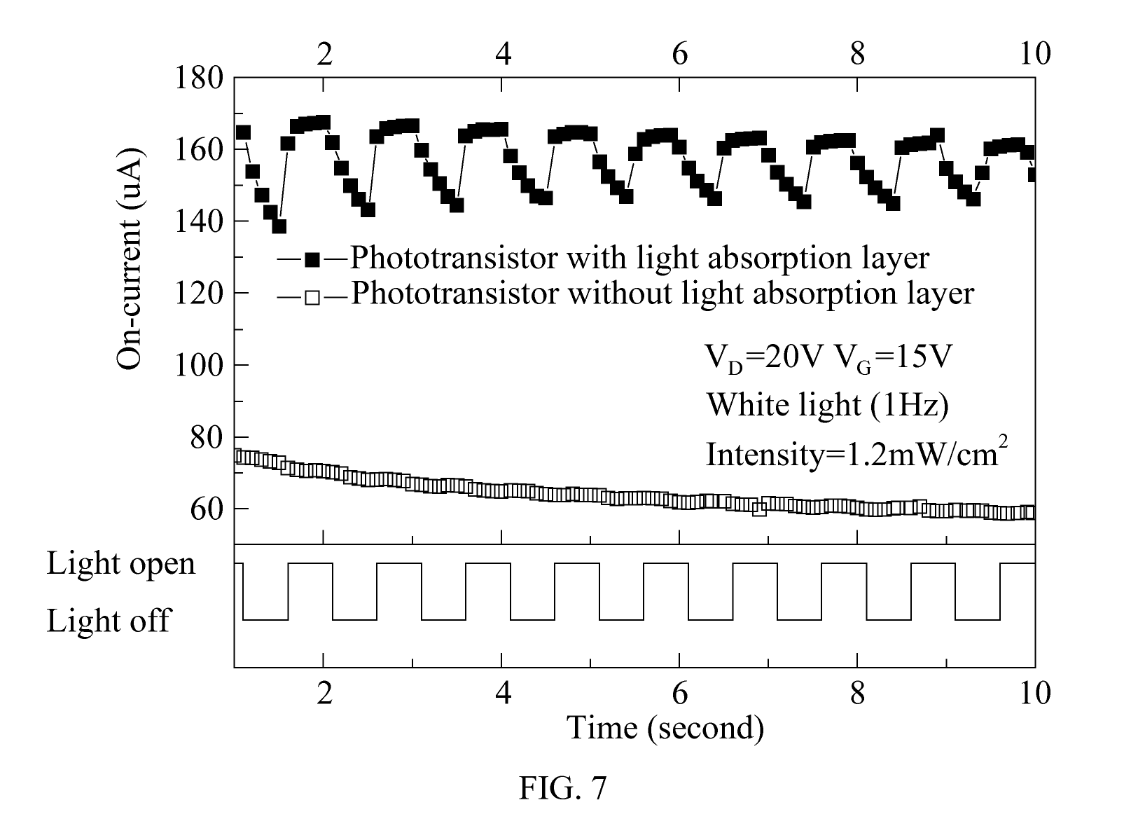

Please refer to FIG. 7 that shows an instant light response curve of the phototransistor of the present invention obtained in a test conducted thereon. As shown, the upper curve represents the instant light response of the P3HT-capped phototransistor to the on/off of light; and the lower curve represents the instant light response of the standard phototransistor without P3HT light absorption layer to the on/off of light. For the P3HT-capped IGZO phototransistor, when the light is switched on or off, the current of the phototransistor would show significant contrast of bright and dark. Therefore, the present invention can be used as an efficient light detecting device.

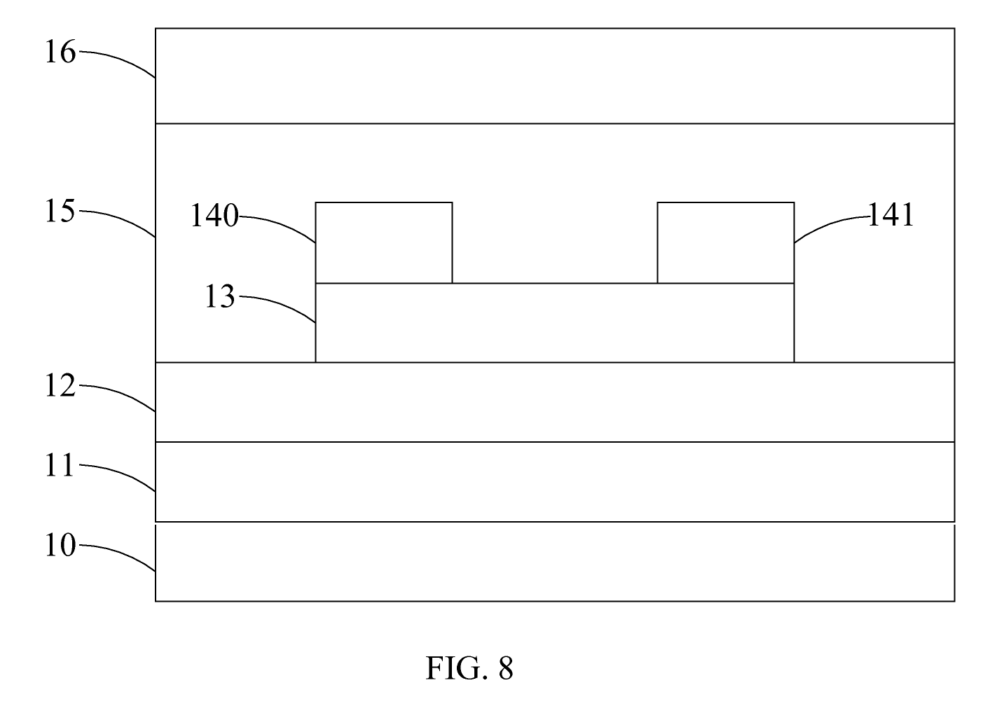

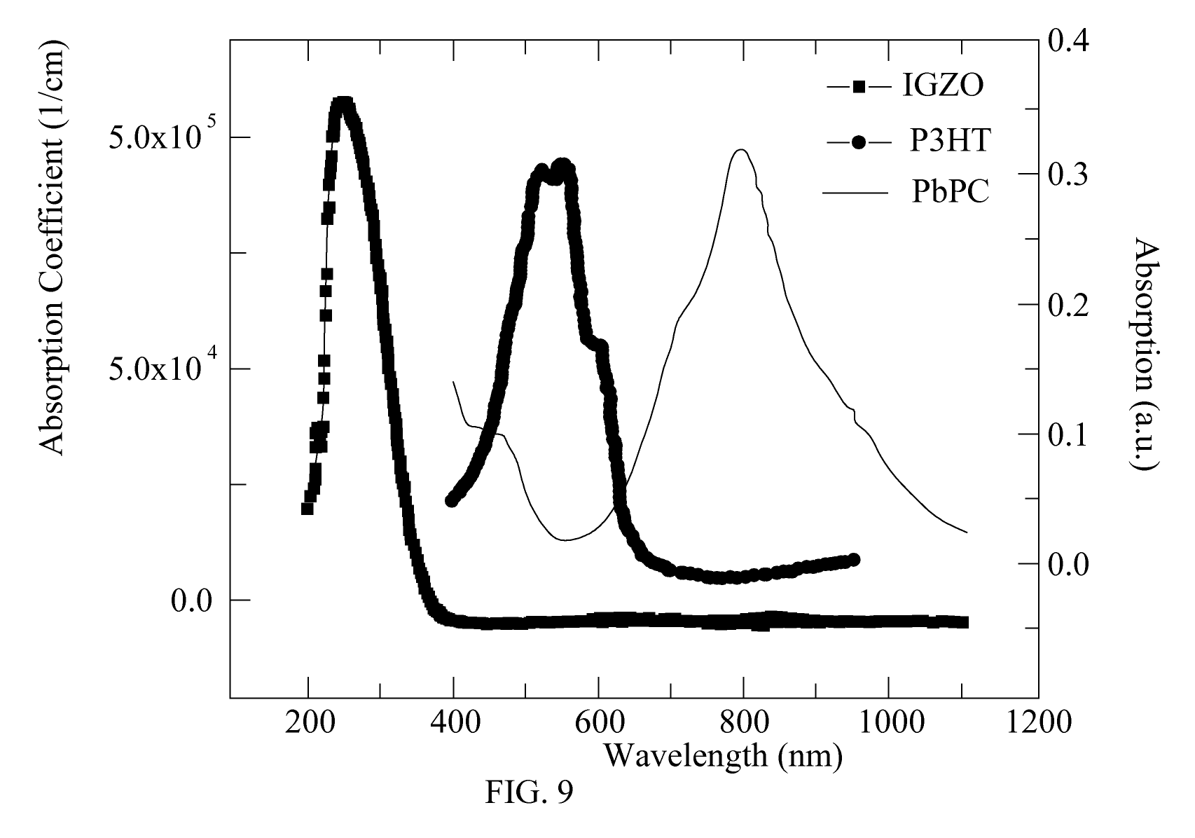

FIG. 8 is a conceptual view of a second embodiment of the phototransistor of the present invention. The phototransistor 1 in the second embodiment of the present invention further includes a filter layer 16 disposed atop the light absorption layer 15. The filter layer 16 has a third bandgap, which is smaller than the first bandgap 130 and unequal to the second bandgap 150. In the second embodiment, the light absorption layer 15 might have relatively low wavelength selectivity. In this case, a filter layer 16 can be cooperatively used to cap the light absorption layer 15 for filtering off electromagnetic waves within some frequency ranges, so that the phototransistor 1 so constructed can have narrow-band sensitivity. For example, a filter layer 16, such as P3HT, can be used to absorb and thereby filter the electromagnetic waves within the visible light range; and then, a light absorption layer 15, such as PbPc, is used to sense infrared light, so that the phototransistor 1 would respond only to the infrared light. Please also refer FIG. 9 that is an absorption spectrum diagram of the phototransistor of the present invention according to the second embodiment thereof. In FIG. 9, there are shown the absorption spectrums of P3HT, PbPc, and IGZO. It can be found these three different materials are quite different in the absorption of different color lights. When the phototransistor 1 is illuminated by light, most of the visible light in the light is absorbed by the P3HT layer, and the remaining near-infrared light is allowed to enter into the PbPc layer. At this light-sensitive PbPc layer, the near-infrared light is absorbed to generate excitons, which are separated at the PbPc/IGZO interface into separated electrons and holes. The electrons migrate into the IGZO layer and are conducted therethrough to produce photocurrent.

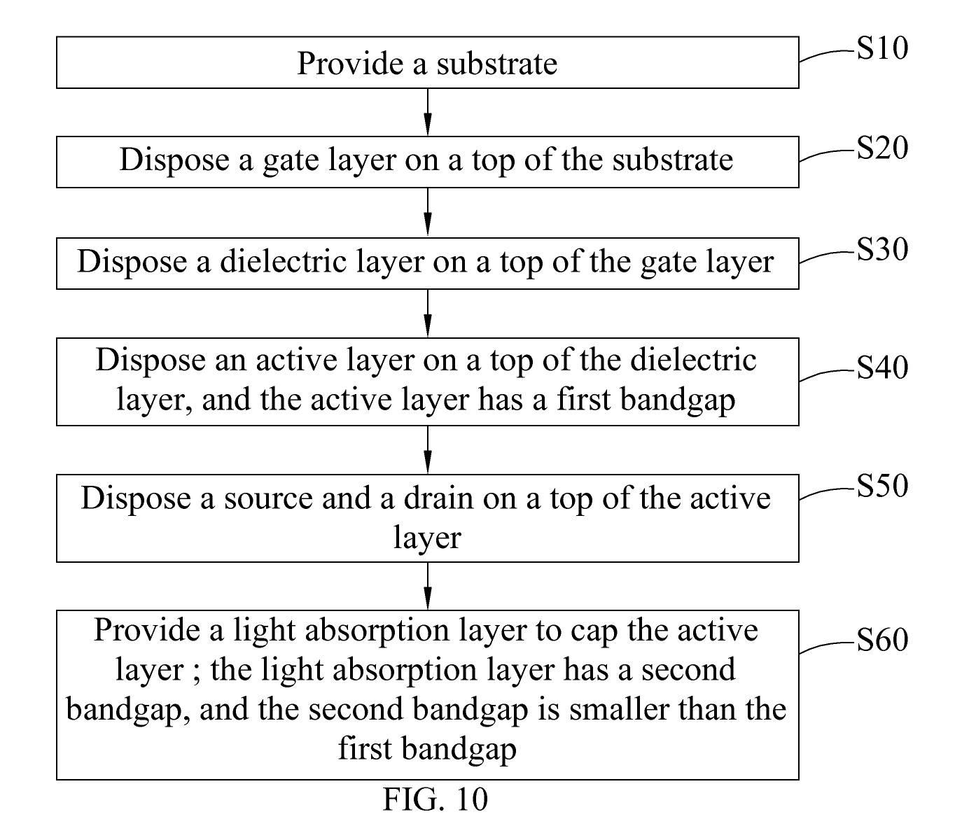

The above description of the phototransistor of the present invention also gives an idea about the manufacturing process thereof. Nevertheless, for the purpose of clarity, a more detailed description of the manufacturing process of the phototransistor of the present invention will now be provided with reference to FIG. 10.

FIG. 10 is a flowchart showing the steps included in a method of manufacturing the phototransistor of the present invention. As shown, the phototransistor manufacturing method includes the steps of providing a substrate (S10); disposing a gate layer on a top of the substrate (S20); disposing a dielectric layer on a top of the gate layer (S30); disposing an active layer having a first bandgap on a top of the dielectric layer (S40); disposing a source and a drain on a top of the active layer (S50); and providing a light absorption layer to cap the active layer (S60), wherein the light absorption layer has a second bandgap, which is smaller than the first bandgap.

According to another embodiment of the present invention not particularly shown in the drawings, after the step S30 in the phototransistor manufacturing method, a step S41 is provided to dispose a source and a drain on a top of the dielectric layer; and then, in a step S51, an active layer is disposed on the source and the drain; and, finally, the same step S60 is performed to complete the manufacturing process.

Since the details of the phototransistor manufactured using the above-described phototransistor manufacturing method are the same as those having been interpreted for the embodiments of the present invention, they are not repeated herein.

According to the present invention, a proper light absorption layer is used to aid the wide bandgap transistor in increasing the photo responsivity thereof. The light absorption layer has efficient light absorption ability, adequate energy level structure, good compatibility with wide bandgap semiconductor, and relatively lowered conductivity (that is, a mechanism that enables the conduction between the source and the drain can be a high resistance of the light absorption layer or a Schottky Barrier that forms an impediment to the conduction between the source and the drain). In other words, the light absorption layer only plays a role of absorbing light and injecting electrons without affecting the operating characteristics of the wide bandgap transistor in dark state, and can therefore effectively increase the light sensitive range of the phototransistor.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A phototransistor, comprising:
a substrate;
a gate layer being disposed on a top of the substrate;
a dielectric layer being disposed on a top of the gate layer;
an active layer having a first bandgap and being disposed on a top of the dielectric layer;
a source and a drain being disposed on a top of the active layer; and
a light absorption layer having a second bandgap and being capped on the active layer, and
the second bandgap being smaller than the first bandgap.

2. The phototransistor as claimed in claim 1, wherein the first bandgap is at least 3 eV.

3. The phototransistor as claimed in claim 1, wherein the active layer is selected from the group consisting of In₂O₃, Ga₂O₃, SnO₂, MgO, ZnO, IZO, IGZO, and any chemical compound having at least one of the above-mentioned materials as a base material thereof.

4. The phototransistor as claimed in claim 1, wherein the light absorption layer is selected from the group consisting of P3HT, PbPc, and Pentacene.

5. The phototransistor as claimed in claim 1, wherein the light absorption layer has a conduction band energy level higher than that of the active layer.

6. The phototransistor as claimed in claim 1, further comprising a filter layer disposed on a top of the light absorption layer; and the filter layer having a third bandgap, which is smaller than the first bandgap and unequal to the second bandgap.

7. A phototransistor, comprising:
a substrate;
a gate layer being disposed on a top of the substrate;
a dielectric layer being disposed on a top of the gate layer;
a source and a drain being disposed on a top of the dielectric layer;
an active layer having a first bandgap and being disposed atop of the source and the drain; and
a light absorption layer having a second bandgap and being capped on the active layer, and
the second bandgap being smaller than the first bandgap.

8. The phototransistor as claimed in claim 7, wherein the first bandgap is at least 3 eV.

9. The phototransistor as claimed in claim 7, wherein the active layer is selected from the group consisting of In₂O₃, Ga₂O₃, SnO₂, MgO, ZnO, IZO, IGZO, and any chemical compound having at least one of the above-mentioned materials as a base material thereof.

10. The phototransistor as claimed in claim 7, wherein the light absorption layer is selected from the group consisting of P3HT, PbPc, and Pentacene.

11. The phototransistor as claimed in claim 7, wherein the light absorption layer has a conduction band energy level higher than that of the active layer.

12. The phototransistor as claimed in claim 7, further comprising a filter layer disposed on a top of the light absorption layer; and the filter layer having a third bandgap, which is smaller than the first bandgap and unequal to the second bandgap.
